(19) United States
(12) Patent Application Publication
(10) Pub. No.: US 2020/0377999 A1
(43) Pub. Date: Dec. 3, 2020

(54) PROCESS FOR COATING AN OXIDE MATERIAL

(71) Applicant: BASF SE, Ludwigshafen am Rhein (DE)

(72) Inventors: Fatih CETINEL, Ludwigshafen (DE); Lothar SEIDEMANN, Ludwigshafen (DE); Frank KLEINE JAEGER, Ludwigshafen (DE); Franz WEBER, Ludwigshafen (DE); Tillmann LIEBSCH, Ludwigshafen (DE)

(73) Assignee: BASF SE, Ludwigshafen am Rhein (DE)

(21) Appl. No.: 16/491,751

(22) PCT Filed: Feb. 21, 2018
(86) PCT No.: PCT/EP2018/054220

§ 371 Date: Sep. 6, 2019

(30) Foreign Application Priority Data
Mar. 8, 2017 (EP) 17159832.9
Oct. 19, 2017 (EP) 17197283.9

(51) Int. Cl. C23C 16/44; C23C 16/40; C23C 16/455; H01M 4/04; H01M 4/36; H01M 4/505; H01M 4/525

(52) U.S. Cl. CPC C23C 16/4417; C23C 16/40; C23C 16/45555; H01M 2004/028; H01M 4/366; H01M 4/505; H01M 4/525; H01M 4/0428

(57) ABSTRACT

The present invention is related to a process for making a coated oxide material, said process comprising the following steps: (a) providing a particulate material selected from lithiated nickel-cobalt aluminum oxides, lithium cobalt oxide, lithiated cobalt-manganese oxides and lithiated layered nickel-cobalt-manganese oxides, (b) treating said cathode active material with a metal alkoxide metal amide or alkyl metal compound, (c) treating the material obtained in step (b) with moisture, and, optionally, repeating the sequence of steps (b) and (c), wherein steps (b) and (c) are carried out in a vessel of which at least one part rotates around a horizontal axis.

The present invention is related to a process for making a coated oxide material, said process comprising the following steps:
(a) providing a particulate material selected from lithiated nickel-cobalt aluminum oxides, lithiated cobalt-manganese oxides and lithiated layered nickel-cobalt-manganese oxides,
(b) treating said cathode active material with a metal alkoxide or metal amide or alkyl metal compound,
(c) treating the material obtained in step (b) with moisture,
   and, optionally, repeating the sequence of steps (b) and (c),
   wherein steps (b) and (c) are carried out in a vessel of which at least one part rotates around a horizontal axis.

Lithium ion secondary batteries are modern devices for storing energy. Many application fields have been and are contemplated, from small devices such as mobile phones and laptop computers through car batteries and other batteries for e-mobility. Various components of the batteries have a decisive role with respect to the performance of the battery such as the electrolyte, the electrode materials, and the separator. Particular attention has been paid to the cathode materials. Several materials have been suggested, such as lithium iron phosphates, lithium cobalt oxides, and lithium nickel cobalt manganese oxides. Although extensive research has been performed the solutions found so far still leave room for improvement.

One problem of lithium ion batteries lies in undesired reactions on the surface of the cathode active materials. Such reactions may be a decomposition of the electrolyte or the solvent or both. It has thus been tried to protect the surface without hindering the lithium exchange during charging and discharging. Examples are attempts to coat the cathode active materials with, e.g., aluminium oxide or calcium oxide, see, e.g., U.S. Pat. No. 8,993,051.

The efficiency of the process, however, may still be improved. Especially in embodiments wherein the particles have a tendency to agglomerate the efficiency sometimes leaves room for improvement both in respect to reaction time and percentage of covered particles as well as percentage of coverage of particles.

It was therefore an objective of the present invention to provide a process by which particulate materials may be coated without an unduly long reaction time wherein such particulate materials have a tendency to form agglomerates. It was further an objective to provide a reactor for performing such a process.

Accordingly, the process as defined at the outset has been found, hereinafter also referred to as inventive process or as process according to the (present) invention. The inventive process is a process for making a coated particulate material.

The term “coated” as used in the context with the present invention refers to at least 80% of the particles of a batch of particulate material being coated, and to at least 75% of the surface of each particle being coated, for example 75 to 99.99% and preferably 80 to 90%.

The thickness of such coating may be very low, for example 0.1 to 5 nm. In other embodiments, the thickness may be in the range of from 6 to 15 nm. In further embodiments, the thickness of such coating is in the range of from 16 to 50 nm. The thickness in this context refers to an average thickness determined mathematically by calculating the amount of thickness per particle surface and assuming a 100% conversion.

Without wishing to be bound by any theory, it is believed that non-coated parts of particles do not react due to specific chemical properties of the particles, for example density of chemically reactive groups such as, but not limited to hydroxyl groups, oxide moieties with chemical constraint, or to adsorbed water.

In one embodiment of the present invention the particulate material has an average particle diameter (D50) in the range of from 3 to 20 μm, preferably from 5 to 16 μm. The average particle diameter can be determined, e.g., by light scattering or LASER diffraction or electroacoustic spectroscopy. The particles are usually composed of agglomerates from primary particles, and the above particle diameter refers to the secondary particle diameter.

In one embodiment of the present invention, the particulate material has a BET surface in the range of from 0.1 to 1 m²/g. the BET surface may be determined by nitrogen adsorption after outgassing of the sample at 200° C. for 30 minutes or more and beyond this accordance with DIN ISO 9277:2010.

The inventive process comprises three steps (a), (b) and (c), in the context of the present invention also referred to as step (a), step (b) and step (c).

Step (a) includes providing a particulate material selected from lithiated nickel-cobalt aluminum oxides, and lithiated cobalt-manganese oxide. Examples of lithiated layered cobalt-manganese oxides are Li₁₊ₓ(CoₑMn_{f}M⁴_{d})₁₋ₓO₂. Examples of layered nickel-cobalt-manganese oxides are compounds of the general formula Li₁₊ₓ(NiₐCo_{b}Mn_{c}M⁴_{d})₁₋ₓO₂, with M⁴ being selected from Mg, Ca, Ba, Al, Ti, Zr, Zn, Mo, V and Fe, the further variables being defined as follows:

zero≤x≤0.2
0.1≤a≤0.8,
zero≤b≤0.5,
0.1≤c≤0.6,
zero≤d≤0.1, and a+b+c+d=1.

In a preferred embodiment, in compounds according to general formula (I)

Li₍₁₊ₓ₎[NiₐCo_{b}Mn_{c}M⁴_{d}]₍₁₋ₓ₎O₂ (I)

M⁴ is selected from Ca, Mg, Al and Ba,

and the further variables are defined as above.

In Li₁₊ₓ(CoₑMn_{f}M⁴_{d})₁₋ₓO₂, e is in the range of from 0.2 to 0.8, f is in the range of from 0.2 to 0.8, the variables M⁴ and d and x are as defined above, and e+f+d=1.

Examples of lithiated nickel-cobalt aluminum oxides are compounds of the general formula Li[NiₕCoᵢAlⱼ]O₂₊ᵣ. Typical values for r, h, i and j are:

h is in the range of from 0.8 to 0.90,

i is in the range of from 0.05 to 0.19,

j is in the range of from 0.01 to 0.05, and

r is in the range of from zero to 0.4.

Particularly preferred are Li₍₁₊ₓ₎[Ni_{0.33}Co_{0.33}Mn_{0.33}]₍₁₋ₓ₎O₂, Li₍₁₊ₓ₎[Ni_{0.5}Co_{0.2}Mn_{0.3}]₍₁₋ₓ₎O₂, Li₍₁₊ₓ₎[Ni_{0.6}Co_{0.2}Mn_{0.2}]₍₁₋ₓ₎O₂, Li₍₁₊ₓ₎[Ni_{0.7}Co_{0.2}Mn_{0.1}]₍₁₋ₓ₎O₂, and Li₍₁₊ₓ₎[Ni_{0.8}Co_{0.1}Mn_{0.1}]₍₁₋ₓ₎O₂, each with x as defined above.

Said particulate material is preferably provided without any additive such as conductive carbon or binder but as free-flowing powder.

In one embodiment of the present invention particles of particulate material such as lithiated nickel-cobalt aluminum oxide or layered lithium transition metal oxide, respectively, are cohesive. That means that according to the Geldart grouping, the particulate material is difficult to fluidize and therefore qualifies for the Geldart C region. In the course of the present invention, though, mechanical stirring is not required.

Further examples of cohesive products are those with a flowability factor ff_{c}≤7, preferably 1<ff_{c}≤7 (ff_{c}=σ₁/σ_{c}; σ₁—major principle stress, σ_{c},—unconfined yield strength) according to Jenike or those with a Hausner ratio f_{H}≥1.1, preferably 1.6≥f_{H}≥1.1 (f_{H}=ρₜₐₚ/ρ_{bulk}; ρₜₐₚ—tapped density measured after 1250 strokes in jolting volumeter, σ_{bulk}—bulk density according to DIN EN ISO 60).

In step (b) of the inventive process, the particulate material provided in step (a) is treated with a metal alkoxide or metal amide or alkyl metal compound. The treatment will be described in more detail below.

Steps (b) and (c) of the inventive process are performed in a vessel or a cascade of at least two vessels, said vessel or cascade—if applicable—also being referred to as reactor in the context of the present invention.

In one embodiment of the inventive process, step (b) is performed at a temperature in the range of from 15 to 1000° C., preferably 15 to 500° C., more preferably 20 to 350° C., and even more preferably 50 to 150° C. It is preferred to select a temperature in step (b) at which metal alkoxide or metal amide or alkyl metal compound, as the case may be, is in the gas phase.

In one embodiment of the present invention, step (b) is carried out at normal pressure but step (b) may as well be carried out at reduced or elevated pressure. For example, step (b) may be carried out at a pressure in the range of from 5 mbar to 1 bar above normal pressure, preferably 10 to 150 mbar above normal pressure. In the context of the present invention, normal pressure is 1 atm or 1013 mbar. In other embodiments, step (b) may be carried out at a pressure in the range of from 150 mbar to 560 mbar above normal pressure.

In a preferred embodiment of the present invention, alkyl metal compound or metal alkoxide or metal amide, respectively, is selected from M¹(R¹)₂, M²(R¹)₃, M³(R¹)_{4-y}H_{y}, M¹(OR²)₂, M²(OR²)₃, M³(OR²)₄, M³[NR²)₂]₄, and methyl alumoxane, wherein

R¹ are different or equal and selected from C₁-C₈-alkyl, straight-chain or branched,

R² are different or equal and selected from C₁-C₄-alkyl, straight-chain or branched,

M¹ is selected from Mg and Zn,

M² is selected from Al and B,

M³ is selected from Si, Sn, Ti, Zr, and Hf, with Sn and Ti being preferred,

the variable y is selected from zero to 4, especially from zero and 1.

Metal alkoxides may be selected from C₁-C₄-alkoxides of alkali metals, preferably sodium and potassium, alkali earth metals, preferably magnesium and calcium, aluminum, silicon, and transition metals. Preferred transition metals are titanium and zirconium. Examples of alkoxides are methanolates, hereinafter also referred to as methoxides, ethanolates, hereinafter also referred to as ethoxides, propanolates, hereinafter also referred to as propoxides, and butanolates, hereinafter also referred to as butoxides. Specific examples of propoxides are n-propoxides and isopropoxides. Specific examples of butoxides are n-butoxides, iso-butoxides, sec.-butoxides and tert.-butoxides. Combinations of alkoxides are feasible as well.

Examples of alkali metal alkoxides are NaOCH₃, NaOC₂H₅, NaO-iso-C₃H₇, KOCH₃, KO-iso-C₃H₇, and K—O—C(CH₃)₃.

Preferred examples of metal C₁-C₄-alkoxides are Si(OCH₃)₄, Si(OC₂H₅)₄, Si(O-n-C₃H₇)₄, Si(O-iso-C₃H₇)₄, Si(O-n-C₄H₉)₄, Ti[OCH(CH₃)₂]₄, Ti(OC₄H₉)₄, Zn(OC₃H₇)₂, Zr(OC₄H₉)₄, Zr(OC₂H₅)₄, Al(OCH₃)₃, Al(OC₂H₅)₃, Al(O-n-C₃H₇)₃, Al(O-iso-C₃H₇)₃, Al(O-sec.-C₄H₉)₃, and Al(OC₂H₅)(O-sec.-C₄H₉)₂.

Examples of metal alkyl compounds of an alkali metal selected from lithium, sodium and potassium, with alkyl lithium compounds such as methyl lithium, n-butyl lithium and n-hexyl lithium being particularly preferred. Examples of alkyl compounds of alkali earth metals are di-n-butyl magnesium and n-butyl-n-octyl magnesium (“BOMAG”). Examples of alkyl zinc compounds are dimethyl zinc and zinc diethyl.

Examples of aluminum alkyl compounds are trimethyl aluminum, triethyl aluminum, triisobutyl aluminum, and methyl alumoxane.

Metal amides are sometimes also referred to as metal imides. Examples of metal amides are Na[N(CH₃)₂], Li[N(CH₃)₂] and Ti[N(CH₃)₂]₄.

Particularly preferred compounds are selected from metal C₁-C₄-alkoxides and metal alkyl compounds, and even more preferred is trimethyl aluminum.

In one embodiment of the present invention, the amount of metal alkoxide or metal amide or alkyl metal compound is in the range of 0.1 to 1 g/kg particular material.

Preferably, the amount of metal alkoxide or metal amide or alkyl metal compound, respectively, is calculate to amount to 80 to 200% of a monomolecular layer on the particular material per cycle.

Step (b) of the inventive process as well as step (c)—that will be discussed in more detail below—are carried out in a vessel of which at least one part rotates around a horizontal axis. Steps (b) and (c) may be carried out in the same or in different vessels.

In a preferred embodiment of the present invention, the duration of step (b) is in the range of from 1 second to 2 hours, preferably 1 second up to 10 minutes.

In a third, optional step, in the context of the present invention also referred to as step (c), the material obtained in step (b) is treated with moisture.

In one embodiment of the present invention, step (c) is carried out at a temperature in the range of from 50 to 250° C.

In one embodiment of the present invention, step (c) is carried out at normal pressure but step (c) may as well be carried out at reduced or elevated pressure. For example, step (c) may be carried out at a pressure in the range of from 5 mbar to 1 bar above normal pressure, preferably 10 to 250 mbar above normal pressure. In the context of the present invention, normal pressure is 1 atm or 1013 mbar. In other embodiments, step (c) may be carried out at a pressure in the range of from 150 mbar to 560 mbar above normal pressure.

Steps (b) and (c) may be carried out at the same pressure or at different pressures, preferred is at the same pressure.

Said moisture may be introduced, e.g., by treating the material obtained in accordance with step (b) with moisture saturated inert gas, for example with moisture saturated nitrogen or moisture saturated noble gas, for example argon. Saturation may refer to normal conditions or to the reaction conditions in step (c).

Although said step (c) may be replaced by a thermal treatment at a temperature in the arrange of from 150° C. to 600° C., preferable 250° C. to 450° C. it is preferred to carry out said step as indicated above.

On one embodiment of the present invention, step (c) has a duration in the range of from 10 seconds to 2 hours, preferable 1 second to 10 minutes.

In one embodiment, the sequence of steps (b) and (c) is carried out only once. In a preferred embodiment, the sequence of steps (b) and (c) is repeated, for example once or twice or up to 40 times. It is preferred to carry out the sequence of steps (b) and (c) two to six times.

Steps (b) and (c) of the inventive process may be carried out continuously or batch-wise. Continuous embodiments are preferred. Especially when the inventive process is carried out in a free-fall mixer a narrow residence time distribution may be achieved.

In one embodiment of the present invention, the charging level of the rotating vessel is in the range of from 30 to 50%.

In one embodiment of the present invention, the reactor in which the inventive process is carried out is flushed or purged with an inert gas between steps (b) and (c), for example with dry nitrogen or with dry argon. Suitable flushing—or purging—times are 1 second to 10 minutes. It is preferred that the amount of inert gas is sufficient to exchange the contents of the reactor of from one to 15 times. By such flushing or purging, the production of by-products such as separate rate particles of reaction product of metal alkoxide or metal amide or alkyl metal compound, respectively, with water can be avoided. In the case of the couple trimethyl aluminum and water, such by-products are methane and alumina or trimethyl aluminum that is not deposited on the particulate material, the latter being an undesired by-product. Said flushing also takes place after step (c), thus before another step (b).

In one embodiment of the present invention, the reactor is evacuated between steps (b) and (c). Said evacuating may also take place after step (c), thus before another step (b). Evacuation in this context includes any pressure reduction, for example 10 to 1,000 mbar (abs), preferably 10 to 500 mbar (abs).

As mentioned before, of steps (b) and (c) are carried out in a vessel of which at least one part rotates around a horizontal axis. Preferably, the entire reactor rotates around a horizontal axis.

Various embodiments of reactor design are possible to perform the steps (b) and (c) of the inventive process. In one embodiment of the present invention, steps (b) and (c) of the inventive process are carried out in a compulsory mixer. Examples of compulsory mixers are paddle mixers and ploughshare mixers.

Even more preferred, at least one out of steps (b) and (c) is performed in a so-called free-fall mixer.

While free fall mixers utilize the gravitational forces for moving the particles compulsory mixers work with moving, in particular rotating mixing elements that are installed in the mixing room. In the context of the present invention, the mixing room is the reactor interior. Examples of compulsory mixers are ploughshare mixers, paddle mixers and shovel mixers. Preferred are ploughshare mixers. Preferred ploughshare mixers are installed horizontally, the term horizontal referring to the axis around which the mixing element rotates. Preferably, the inventive process is carried out in a shovel mixing tool, in a paddle mixing tool, in a Becker blade mixing tool and, most preferably, in a ploughshare mixer in accordance with the hurling and whirling principle.

In a preferred embodiment of the present invention, the inventive process is carried out in a free fall mixer. Free fall mixers are using the gravitational force to achieve mixing. In a preferred embodiment, steps (b) and (c) of the inventive process are carried out in a drum or pipe-shaped vessel that rotates around its horizontal axis. In a more preferred embodiment, steps (b) and (c) of the inventive process are carried out in a rotating vessel that has baffles.

In one embodiment of the present invention, the rotating vessel has in the range of from 2 to 100 baffles, preferably 2 to 20 baffles. Such baffles are preferably flush mount with respect to the vessel wall.

In one embodiment of the present invention, such baffles are axially symmetrically arranged along the rotating vessel, drum, or pipe. The angle with the wall of said rotating vessel is in the range of from 5 to 45° , preferably 10 to 20°. By such arrangement, they can transport coated cathode active material very efficiently through the rotating vessel.

In one embodiment of the present invention, said baffles reach in the range of from 10 to 30% into the rotating vessel, referring to the diameter.

In one embodiment of the present invention, said baffles cover in the range of from 10 to 100%, preferably 30 to 80% of the entire length of the rotating vessel. In this context, the term length is parallel to the axis of rotation.

Said baffles may be concave or flat. Concave baffles may be bend in the direction of the rotation or against the direction of rotation. Preferably, the baffles are bend against the direction of rotation.

In one embodiment of the present invention the vessel or at least parts of it rotates with a speed in the range of from 5 to 200 rounds per minute, preferred are 5 to 60 rounds per minute.

In a preferred version of the present invention, which allows for the pneumatic conveying of said particulate material, a pressure difference in the range of from up to 4 bar is applied. Coated particles may be blown out of the reactor or removed by suction.

In one embodiment of the present invention, the inlet pressure is higher but close to the desired reactor pressure. Pressure drops of gas inlet have to be compensated.

In the course of the inventive process strong shear forces are introduced due to the shape of the reactor, the particles in the agglomerates are exchanged frequently, which allows for the accessibility of the full particle surface. By the inventive process, particulate materials may be coated in short time, and in particular cohesive particles may be coated very evenly.

In a preferred embodiment of the present invention the inventive process comprises the step of removing the coated material from the vessel or vessels, respectively, by pneumatic conveying, e.g. 20 to 100 m/s.

In one embodiment of the present invention, the exhaust gasses are treated with water at a pressure above one bar and even more preferably higher than in the reactor in which steps (b) and (c) are performed, for example in the range of from 1.010 to 2.1 bar, preferably in the range of from 1.005 to 1.150 bar. The elevated pressure is advantageous to compensate for the pressure loss in the exhaust lines.

By the inventive process, particulate materials may be coated in short time, and in particular cohesive particles may be coated very evenly. In addition, the abrasion is only low and so only very reduced dusting may be observed. Especially in embodiments where a free-fall mixer is applied for steps (b) and (c), few contacts of electrode active material particles with the wall of the vessel—that may lead to abrasion—are observed.

1. A process for making a coated oxide material, the process comprising:
(a) providing a particulate material selected from the group consisting of lithiated nickel-cobalt aluminum oxides, lithiated cobalt-manganese oxides and lithiated layered nickel-cobalt-manganese oxides,
(b) treating the particulate active material with a metal alkoxide, a metal amide or an alkyl metal compound,
(c) treating the material obtained in step (b) with moisture, and,
optionally, repeating the sequence of steps (b) and (c),
wherein steps (b) and (c) are carried out in a vessel of which at least one part rotates around a horizontal axis.

2. The process according to claim 1, wherein the alkyl metal compound, the metal alkoxide, or the metal amide, respectively, is selected from the group consisting of M¹(R¹)₂, M²(R¹)₃, M³(R¹)_{4-y}H_{y}, M¹(OR²)₂, M²(OR²)₃, M³(OR²)₄, M³[NR²)₂]₄, and methyl alumoxane, wherein:
R¹ are different or equal and selected from C₁-C₈-alkyl, straight-chain or branched,
R² are different or equal and selected from C₁-C₄-alkyl, straight-chain or branched,
M¹ is selected from Mg and Zn,
M² is selected from Al and B,
M³ is selected from Si, Sn, Ti, Zr, and Hf, and
the variable y is selected from zero to 4.

3. The process according to claim 1, wherein the particulate material is a lithiated layered nickel-cobalt-manganese oxide of formula (I):
Li(₁₊ₓ)[NiₐCo_{b}Mn_{c}M⁴_{d}]₍₁₋ₓ₎O₂ (I)
wherein:
M⁴ is selected from Mg, Ca, Ba, Al, Ti, Zr, Zn, Mo, V and Fe,
zero≤x≤0.2
0.1≤a≤0.8,
Zero≤b≤0.5,
0.1≤c≤0.6,
zero≤d≤0.1, and
a+b+c+d=1.

4. The process according to claim 1, wherein steps (b) and (c) are performed in a rotating vessel that has baffles.

5. The process according to claim 4, wherein the vessel is cylindrical.

6. The process according to claim 4, wherein the rotating vessel has in the range of from 2 to 20 baffles.

7. The process according to claim 1, wherein particles of lithiated nickel-cobalt aluminum oxide or lithiated layered nickel-cobalt-manganese oxide, respectively, are cohesive.

8. The process according to claim 1, wherein the vessel or at least parts of it rotates with a speed in the range of from 5 to 200 rounds per minute.

9. The process according to claim 1, wherein step (b) is performed at a temperature in the range of from 15 to 350° C.

10. The process according to claim 1, wherein the reactor is flushed with an inert gas between steps (b) and (c).

11. The process according to claim 1, wherein the reactor is evacuated between steps (b) and (c).

12. The process according to claim 1, wherein steps (b) and (c) are carried out in at least two different vessels of which at least one part rotates along a horizontal axis each.

13. The process according to claim 1, further comprising:
removing the coated oxide material from the vessel or vessels, respectively, by pneumatic conveying.
